(19) United States
(12) Patent Application Publication
(10) Pub. No.: US 2024/0296265 A1
(43) Pub. Date: Sep. 5, 2024

(54) System and Method of Preparing and Pumping a Cement Composition

(71) Applicant: Halliburton Energy Services, Inc., Houston, TX (US)

(72) Inventors: Abdulmalek Ahmed SHAMSAN, Dammam (SA); Siva Rama Krishna JANDHYALA, Houston, TX (US); Walmy Cuello JIMENEZ, Houston, TX (US)

(21) Appl. No.: 18/116,067

(22) Filed: Mar. 1, 2023

(51) Int. Cl. G06F 30/28

(52) U.S. Cl. CPC G06F 30/28

(57) ABSTRACT

A method of designing a cement slurry comprising retrieving, by a design process, a material inventory comprising a geographic cement and a set of design parameters. Determine, by a model within the design process, a design slurry composition based on at least one of the set of design parameters. Determine with a model using a machine learning process, a predicted thickening time by comparing the design slurry composition, the material inventory, and the set of design parameters to a plurality of datasets within a geographic database. Generate a slurry design in response to a set of validation results of a test sample exceeding the threshold value. Place the slurry design into a wellbore with a pumping operation.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

In well cementing, such as well construction and remedial cementing, cement compositions are commonly utilized. Cement slurries may be used in a variety of subterranean applications. For example, in subterranean well construction, a pipe string (e.g., casing, liners, expandable tubulars, etc.) may be run into a well bore and cemented in place. The process of cementing the pipe string in place is commonly referred to as “primary cementing.” In a typical primary cementing method, a cement slurry may be pumped into an annulus between the walls of the wellbore and the exterior surface of the pipe string disposed therein. The cement slurry may set in the annular space, thereby forming an annular sheath of hardened, substantially impermeable cement (i.e., a cement sheath) that may support and position the pipe string in the well bore and may bond the exterior surface of the pipe string to the subterranean formation. Among other things, the cement sheath surrounding the pipe string functions to prevent the migration of fluids in the annulus, as well as protecting the pipe string from corrosion. Cement slurries also may be used in remedial cementing methods, for example, to seal cracks or holes in pipe strings or cement sheaths, to seal highly permeable formation zones or fractures, to place a cement plug, and the like.

A challenge in well cementing is the development of satisfactory properties of the cement during and after placement. Oftentimes several cement slurries with varying additives are tested to see if they meet the material engineering requirements for a particular well. The process of selecting the components of the cement slurry is usually done by a best guess approach by utilizing previous slurries and modifying them until a satisfactory solution is reached. The process may be time consuming, and the resulting slurry may be complex. Furthermore, the cement components available in any one particular region may vary in slurry from those of another region thereby further complicating the process of selecting a correct slurry.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1A is a logical flow diagram of a method to determine a probability of job outcome according to an embodiment of the disclosure.

FIG. 1B is a logical flow diagram of the model with input variables according to an embodiment of the disclosure.

FIG. 2A is a data chart of an exemplary validation of the model according to an embodiment of the disclosure.

FIG. 2B is another data chart of an exemplary validation of the model according to an embodiment of the disclosure.

FIG. 3 is a cut-away illustration of a primary cementing operation according to an embodiment of the disclosure.

FIG. 4 is a block diagram of a computer system suitable for implementing one or more embodiments of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

The present disclosure may generally relate to cementing methods and systems. More particularly, embodiments may be directed to designing cement slurries based at least partially on a thickening time model.

Cement slurries may contain cement, supplementary cementitious additives, inert materials, and chemical additives. A cement slurry for use in cementing wellbores is typically mixed at a wellbore pad site using cement mixing equipment and pumped into the wellbore using cement pumps. After the cement slurry is mixed, there is a time lag between when the cement is in a liquid state and when the cement begins to set. As the cement slurry begins to set, the slurry gradually becomes more viscous until fully set. There may be an upper limit of viscosity beyond which the cement slurry becomes too viscous to pump. In general, the upper limit of viscosity is typically defined to be when the fluid has a consistency of greater than 70 Bearden units of consistency (“Bc”). However, there may be other considerations where the cement slurry would be considered unpumpable and thus a Bc value of 30, 50, 70, 100, or any other value may be selected as being “unpumpable.” To determine the consistency or Bc value of a cement slurry, an atmospheric or a pressurized consistometer may be used in accordance with the procedure for determining cement thickening times set forth in API RP Practice 10B-2, Recommended Practice for Testing Well Cements, First Edition, July 2005. The time to reach the selected Bearden units of consistency is reported as thickening time. It is often a design criteria for a cement slurry to have a long enough thickening time such that there is enough time to pump the required volume of cement into the wellbore while also not having too long of a thickening time where there is excessive downtime from waiting on the cement to set. The thickening time for a cement slurry may be a function of pressure, temperature, temperature ramp rate, density of the cement slurry, and composition of the cement slurry.

Designing a cement slurry to have a desired thickening time is an inefficient trial and error process often requiring multiple iterations of selecting slurry components and mass fractions thereof and testing a thickening time for a slurry formed from the slurry components. Small changes in composition may result in widely varying thickening times which is further compounded by cementitious materials varying across different geographical areas. As such, a cement recipe that is prepared in one region may have a different thickening time than the same recipe prepared in a different region with same class of materials, due to the differences in minerology and manufacturing processes of the cement components. The differences in thickening times may be difficult to predict as the thickening time of a cement slurry is a complex function of various interacting factors.

Cement slurries are typically blended with chemical additives such as accelerators, retarders, fluid loss control additives, lost circulation control additives, rheological modifiers, and other chemical additives to impart desirable properties on the cement slurry such as fluid loss control, rheology, stability, and thickening time. The additive package that can satisfy all of these properties is typically determined through an iterative process. This is because one additive used to satisfy one property may affect another property. For example, a fluid loss control additive may retard the cement slurry. Thus, when designing for thickening time, the effects of each additive on thickening time must be accounted for.

One solution to the problem of the inefficient iterative process can utilize a machine learning process to design a cement slurry. In some embodiments, a model utilizing a machine learning process can determine a composition of a cement slurry based on an inventory of materials, a set of design parameters, and a database of test results. The model can utilize cementitious materials with properties specific to a geographic area or region such as a Portland cement blend manufactured in the geographic area. The database of test results can provide a learning dataset comprising test results of cementitious materials specific to the geographic area. The model can determine a cement slurry with the inventory of materials available to the geographic area based on the learning dataset. The model can be trained by adding validation test results to the database of test results. A method of designing a cement slurry with a model and a database of validation test results can reduce the time required to design and validate a new cement slurry.

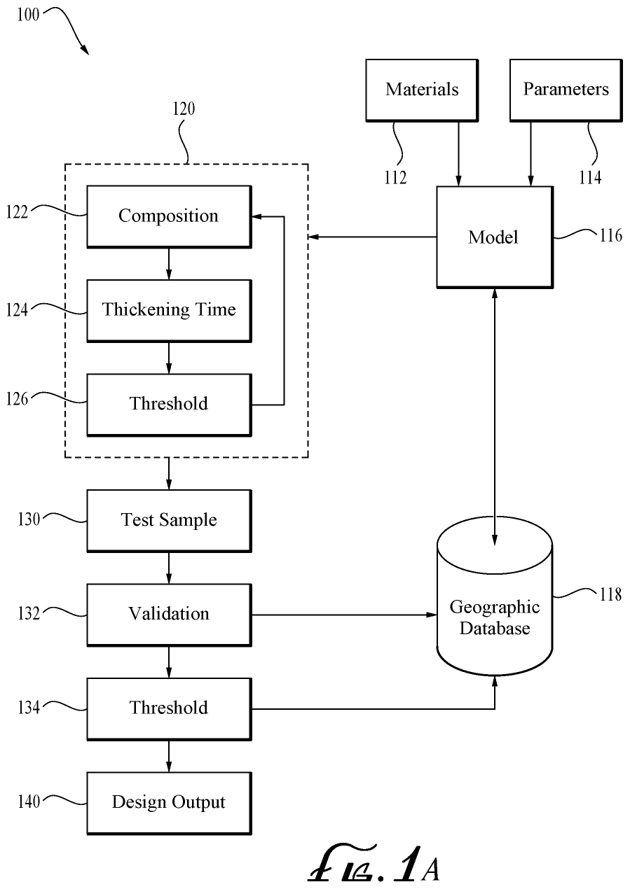

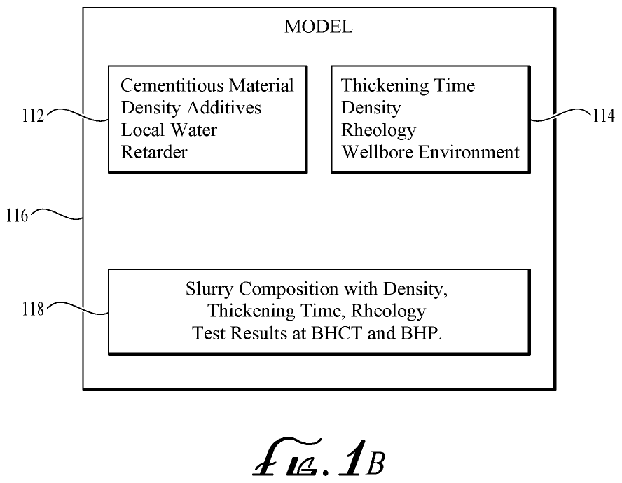

A cement slurry designed for a specific geographical location can be determined with a design process that utilizes a geographic database of test results. Turning now to FIG. 1A, a method 100 for determining a cement slurry composition with a desired thickening time is described. In some embodiments, a model 116 can utilize a geographic database 118, a material inventory 112, and a set of design parameters 114 as inputs for the model 116. The model 116 may utilize a machine learning process or a neural network to output a cement slurry design based on a training dataset. A validation step, e.g., validation 132, can further train, update, or calibrate the model 116 by adding test results from the validation step to the training dataset, e.g., geographic database 118.

The model 116 can be a machine learning model or neural network model with a training set of data within the geographic database 118. The training set of data comprises a plurality of test results from corresponding or known slurry designs. This training set of data may comprise a known data format and/or a consistent data format. The model may be trained with supervised learning, unsupervised learning, semi-supervised learning, or combinations thereof. In a scenario, the model 166 can be trained with supervised learning utilizing a plurality of known slurry designs with corresponding known test results. This initial set of known slurry designs corresponding test results can be a training dataset. In another scenario, the model 166 can be trained with unsupervised learning utilizing a historical database wherein the model 166 compares a slurry design and corresponding test results from the historical database to the training dataset and inputs the data from the historical database in response to an agreement with the training dataset. In some embodiments, the model 166 can query a user, e.g., service personnel, in response to the data from the historical database not matching or not in agreement with the training dataset.

In some embodiments, the machine learning model, e.g., model 116, can be initialized with a training set of data and subsequently trained with a historical database of slurry designs and corresponding test results. In some embodiments, the trained model, e.g., model 116, can be calibrated or updated by subsequent slurry designs and validation test results.

In some embodiments, the material inventory 112 comprises a cementitious material that is sourced, mined, blended, manufactured, or combinations thereof in a specific geographic area, for example, a country in the middle east. This cementitious material may be a type of Portland cement, e.g., Portland class G, and may have a percentage composition of Bogue compound compositions unique to a geographical location. For example, the cementitious material may have a higher percent composition of any one or more of C3A, e.g., tricalcium aluminate, C4AF, e.g., tetracalcium alumino ferrite, C3S, e.g., tricalcium silicate, or C2S, e.g., dicalcium silicate. The cementitious material unique to the specific geographical location can be referred to as geographical cement.

The material inventory 112 can also include supplemental cementitious material (SCM), density additives, and chemical additives that are sourced, mined, blended, manufactured or otherwise obtained in a specific geographic area. SCM can include fly ash, ground blast furnace slag, silica fume, calcium carbonate, and natural pozzolans such as calcined clays, shale, and metakaolin. Density additives can include inert materials such as ilmenite, hematite, and barite. Chemical additives can comprise accelerators, retarders, fluid loss control additives, lost circulation control additives, rheological modifiers, and other chemical additives to impart desirable properties on the cement slurry. An accelerator, e.g., calcium chloride, can counteract a delay in the setting time caused by the addition of other additives. Retarders can inhibit hydration and delay the curing process to counteract the accelerating effect of the elevated temperatures found in the wellbore. An example of a retarder includes hydroxycarboxylic acid, carboxymethyl hydroxyethyl cellulose, and organophosphates. The design of a cementitious composition may not include the fluid loss control additive nor the lost circulation additive. The addition of fluid loss control additives and/or lost circulation additives may be operational driven decisions. For example, the fluid loss control additive may be added during the pumping operation in response to a low pressure zone within a subterranean formation and subsequent loss of fluid volume.

The material inventory 112 can include geographically sourced water. The water source utilized at a wellsite location may be unique to the wellsite location or a volume of water may be transported from a local source proximate to the wellsite to the pumping operation at the wellsite. The geographical water may have a unique mineral content, a hardness of water (e.g., hard water versus soft water), turbidity, pH value or pH level, chloride content, dissolved gas content (e.g., oxygen content), nitrogen content, organic matter, bacteria content, metal ions (e.g., iron and/or manganese), suspended solids, total solid content, or combinations thereof. The material inventory 112 may comprise the properties of one or more geographical water sources used at a wellsite or within a geographical region.

The set of design parameters 114 comprises fluid loss control requirements, rheology requirements, stability requirements, slurry density requirements, wellbore environment, and thickening time requirements. The fluid loss control requirement can be based on historical pumping operations within the same formation or within the same geographical area. The rheology requirements can counteract pumping operational limits such as applied pumping pressure. The wellbore environment comprises wellbore geometry, pressure, temperature, and measured depth of the wellsites found within a specific geographical area. The wellbore geometry comprises wellbore size, e.g., diameter, measured depth, casing string, or combinations thereof. The wellbore temperature requirement can include the bottom hole circulating temperature (BHCT), e.g., temperature at the bottom of the casing string. The wellbore environment pressure can include the bottom hole pressure (BHP), e.g., hydrostatic pressure at the bottom of the casing string.

The geographic database 118 comprises laboratory test results, from a block for validation 132, of each cement slurry composition 122 designed at the service center proximate to the specific geographical location. The geographic database 118 can train the model 116 by providing feedback of cement slurry composition 122 via a set of test results. The test results of every iteration of a given cement slurry composition 122 can increase the number or volume of datasets within the geographical database 118 and potentially reduce the error rate of test results, e.g., validation 132, compared to cement slurry composition 122. The geographic database 118 can be located on a storage computer or similar suitable computer system.

In some embodiments, the model 116 can be calibrated, e.g., trained, by a set of test results that iterate a given cement slurry to a desired thickening time. In some embodiments, the model 116 can be calibrated by increasing the size of the validation dataset within the database 118. In some embodiments, the calibration of the model 116 can include the removal of erroneous data and result in a reduction of the error rate.

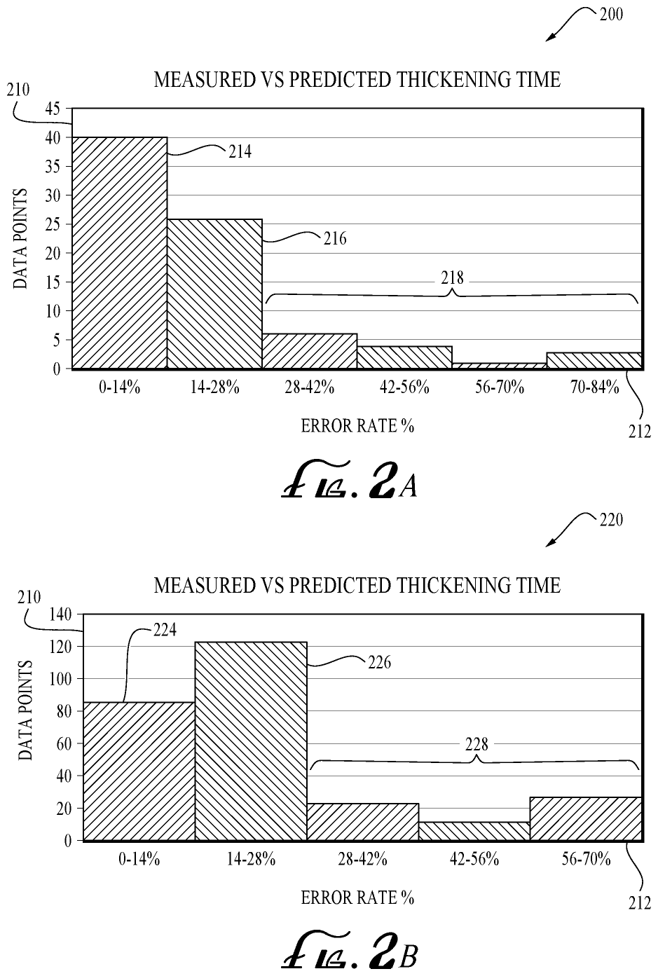

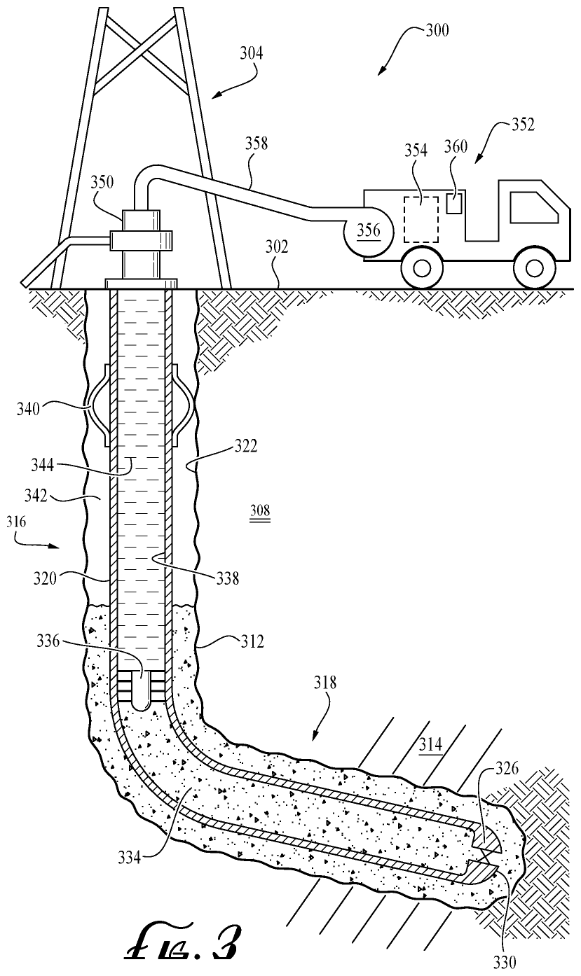

The model 116 can be validated by comparing the predicted thickening time, e.g., thickening time from block 124, to the training dataset. A set of experimental results of a model validation is shown in FIG. 2A with a data chart 200. In some embodiments, an exemplary validation of the model 116, as illustrated with data chart 200, can include a comparison of measured thickening time versus predicted thickening time, e.g., predicted thickening time 124. An error rate, e.g., percentage, can be determined by comparing the predicted thickening time to the measured thickening time. For example, the error rate can be determined by a ratio of predicted thickening time to measured thickening time. In some embodiments, the error rate can be linear, e.g., the error rate is proportional to the size of the devotion. In some embodiments, the error rate can include a weighting factor and yield non-linear results. The model validation can include an error rate threshold, for example, 30 percent. Thus, the model 116 can be validated with error rate below the error rate threshold, e.g., 30 percent.

The exemplary validation of the model 116 can be shown by the number of data points below the error rate threshold in the data chart 200. The data chart 200 can include a first axis 210 for a number of data points and a second axis 212 for an error rate as a percentage. The number of data points corresponding to the first axis 210 can be the number of predicted thickening time and validated tests, e.g., measured thickening time, for a corresponding cement slurry. The error rate corresponding to the second axis 212 can be plotted as individual data points or grouped into a range of error rates, for example, 14% to 28%. In the data chart 200, a first group 214 of validation data points comprises 40 validation data points, e.g., slurry designs with validation tests, with an error rate between zero and 14 percent. A second group 216 of validation data points comprises 26 validation data points with an error rate between 14 and 28 percent. A third group 218 of validation data points comprises 14 validation data points with an error rate greater than 28 percent. The exemplary validation of the model 116 can comprise 66 of 80 validation data points showing 82.5 percent of the validation data points has an error rate below a threshold value of 30 percent or said another way, 17.6 percent of the validation data points were above the error rate threshold of 30 percent.

The model 116 can be further validated by increasing the size of the dataset. Turning now to FIG. 2B, an exemplary validation of the model 116 is illustrated with data chart 220. The data chart 220 can include a comparison of measured thickening time versus predicted thickening time 124 for a larger dataset. The dataset for chart 220 contains 274 validation data points versus 80 validation data points for chart 200 for an increase of 342.5 percent. In the data chart 220 of FIG. 2B, a first group 224 and a second group 226 of validation data points comprises validation data points, e.g., slurry designs with validation tests, with an error rate below 28 percent. A third group 228 of validation data points comprises 44 validation data points with an error rate above 30 percent. The exemplary validation of the model 116 can comprise 230 of 274 validation data points showing 84 percent of the validation data points has an error rate below a threshold value of 30 percent. Thus, the increase in data size from 80 to 274 validation data points decreased the error rate above the threshold value of 30 percent from 17.6 percent to 16 percent.

In some embodiments, the model 116 can be further validated by increasing the size of the dataset and/or cleaning the dataset. For example, the model 116 can be calibrated by adding additional validation datasets to the geographic database 118 during the validation of each slurry design. In another scenario, the dataset can be cleaned by re-testing or re-validating slurry designs with outlier validation results. The increase in size of the dataset and/or cleaning the dataset within the geographic database 118 can further reduce the error rate from 16 percent to 15, 14, 13, 12, 11, 10, 9, 8, 7, 6, 5, 4, 3, 2, 1, or 0 percent or any value below 16 percent.

The method of determining a cement slurry composition with a desired thickening time utilizing a validated model, e.g., model 116, can begin by retrieving a materials inventory 112 and a set of design parameters 114 from a user, a database, a remote location, or combinations thereof. In some embodiments, a user, e.g., service personnel, can input the materials inventory 112 and the set of design parameters 114 into the model 116.

At block 120, the design process for the model 116 to determine a slurry composition 122 by comparing the materials inventory 112 and the set of design parameters 114 to the geographic database 118 is described. For example, turning to FIG. 1B, the model 116 can compare a plurality of validation datasets from the geographic database 118, e.g., density, thickening time, rheology test results at BHCT and BHP for each corresponding slurry composition, to a materials inventory 112 and a set of design parameters 114. The test results within the geographic database 118, e.g., the training dataset, may be datasets unique to the geographic region. For example, the slurry composition 122 determined by the model comprises geographical cement, e.g., cementitious materials specific to the geographical region, a local source of water, SCM, density additives, and chemical additives from the geographical region. Likewise, the dataset, e.g., test results, within the geographical database 118 comprise test results obtained in laboratory conditions of slurry compositions comprising geographical cement, a source of local water, SCM, density additives, an chemical additives obtained within the geographical region.

Returning to FIG. 1A, at block 120 the model 116 can determine a cement slurry composition 122, also referred to as slurry composition 122, based on a single parameter, e.g., slurry density. The model 116 can step to block 124 to determine a predicted thickening time as a function of the wellbore environment, retarder concentration, and slurry density as shown in Equation 1:

Thicking Time(BC)=f(BHCT,BHP,Retarder,Density,TVD) Equation 1

At step 126, the model 116 can compare the value of the thickening time determined in block 124 to a target value provided by the set of design parameters 114. The model 116 can return to block 122 if the value of the thickening time from block 124 is not within, or outside of, a threshold range of the target value.

At block 130, the model 116 can output a design composition, e.g., slurry composition 122, for validation in response to the value of thickening time from block 124 being within a threshold range of the target value (e.g., step 126). A test sample 130 can be produced from the design composition determined in slurry composition 122.

At block 132, the design composition, e.g., slurry composition 122, can be validated by a set of tests performed within laboratory conditions, also referred to as validation 132. The set of validation tests can comprise thickening time, slurry density, rheology, fluid loss control, and stability. The results of the validation tests, e.g., test results, can be stored within the geographic database 118. In some embodiments, the geographic database is located on a local computer system, e.g., a storage computer, a server, or other suitable storage device. In some embodiments, the geographic database is located on a remote computer system, e.g., a storage computer, a network slice on a cloud computing platform, a virtual computer, or other suitable storage device. The remote computer system can be communicatively connected to one or more local computer systems by wired, wireless, or both communication means. In some embodiments, the geographic database 118 retrieves the test results of the validation tests from a local computer system.

At step 134, the model 116 and/or the service personnel can compare the value of the thickening time determined in the block for validation 132 to a target value provided by the set of design parameters 114. The model 116 can return to block 120 if the value of the thickening time from block 124 is out of range of a threshold range of the target value. The test results determined in the validation 132 can be compared to the design composition, e.g., slurry composition 122, and the predicted thickening time determined in block 124. An error value can be generated from the comparison of the predicted thickening time and the test results. The error value can be transmitted to the geographical database 118 and/or to the model 116.

The model 116 can receive and/or retrieve the error value, the design composition, the predicted thickening time, and the dataset from the validation 132. The model 116 can return to block 120 to iterate the slurry composition 122 with the dataset from the validation 132 and the plurality of datasets within the geographic database 118 to reduce the error value.

If the value of the thickening time from validation 132 is within a threshold range of the target value, the method 100 can output the final slurry design at block 140, also referred to as final slurry design 140. The final slurry design 140 can comprise the slurry composition 122. In some embodiments, the final slurry design 140 can comprise a pump schedule, e.g., a series of steps to mix and pump the slurry into a wellbore with pumping equipment.

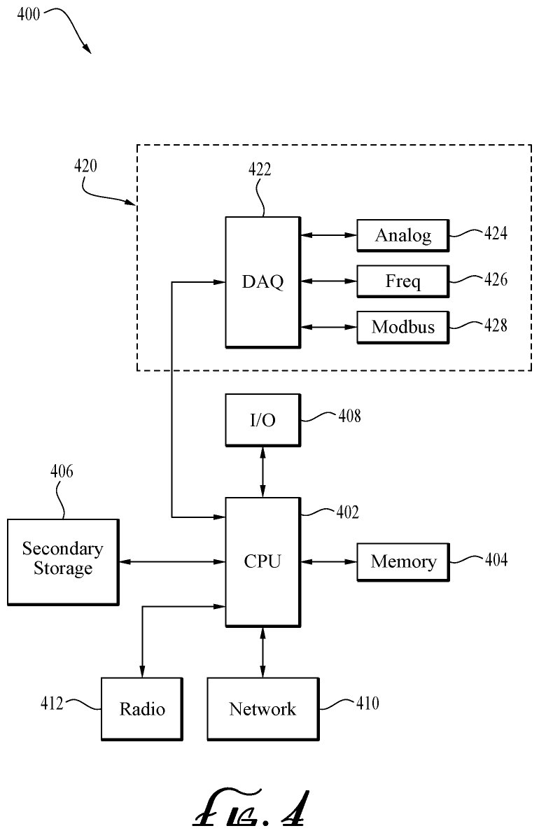

The final slurry design 140 can be transported out to a remote wellsite with the assigned pumping equipment to perform a pumping operation. Turning now to FIG. 3, a wellbore treatment operation 300 utilizing the final slurry design 140 is illustrated. In some embodiments, the wellsite may be on land and the final slurry design 140, e.g., cement blend, pump schedule, and inventory of pump units 352, is optimized for a wellsite on land. In some embodiments, the wellsite may be offshore and the final slurry design 140 is optimized for a wellsite offshore. For example, the pump unit 352 utilized offshore may be skid mounted whereas the pump unit 352 utilized on land may be truck mounted.

A casing string 320 can be conveyed into the wellbore 312 by the drilling rig 304, a workover rig, an offshore rig, or similar structure. A wellhead 350 may be coupled to the casing string 320 at surface 302. The pump unit 352, located offshore or on land, can be fluidically coupled to a wellhead 350 by a supply line 358. The wellbore 312 can extend in a substantially vertical direction away from the earth's surface 302 and can be generally cylindrical in shape with an inner bore 322. At some point in the wellbore 312, the vertical portion 316 of the wellbore 312 can transition into a substantially horizontal portion 318. The wellbore 312 can be drilled through the subterranean formation 308 to a hydrocarbon bearing formation 314. Perforations made during the completion process that penetrate the casing string 320 and hydrocarbon bearing formation 314 can enable the fluid in the hydrocarbon bearing formation 314 to enter the casing string 320.

In some embodiments, the pump unit 352, also called a cementing unit, comprises a mixing system 354, a pumping mechanism 356, and a unit controller 360. The mixing system 354 can mix the slurry design 140 with a liquid, e.g., local water, to form a cement slurry 334. The pumping mechanism 356 can deliver the cement slurry 334 from the mixing system 354 to the wellbore 312 via the supply line 358. The unit controller 360 may be a computer system suitable for communication with the service personnel and control of the mixing system 354 and the pumping mechanism 356 as will be described further herein.

In some embodiments, the wellbore 312 can be completed with a cementing process that follows a cementing pumping procedure, e.g., pump schedule, to place a cement slurry 334 between the casing string 320 and the wellbore 312. The wellhead 350 can be any type of pressure containment equipment connected to the top of the casing string 320, such as a surface tree, production tree, subsea tree, lubricator connector, blowout preventer, or combination thereof. The wellhead 350 can include one or more valves to direct the fluid flow from the wellbore and one or more sensors that measure pressure, temperature, and/or flowrate data. The pump unit 352 can follow a pumping procedure with multiple sequential steps to mix a cement blend, e.g., slurry design 140, with water, e.g., local water, to form a cement slurry 334 and place the cement slurry 334 into the annular space 342. The pumping procedure can include steps of pumping a spacer fluid to separate the drilling fluid, e.g., drilling mud, from the cement slurry 334. The pumping procedure can include instruction for downhole tools, for example, releasing and pumping a cementing wiper plug 336, or similar downhole equipment, to physically separate the drilling fluid from the cement slurry 334. The wiper plug 336 comprises a plurality of flexible fins, or wipers, that sealingly engage the inner surface 338 of the casing string 320 with a sliding fit. The pump unit 352 can pump a predetermined volume of cement slurry 334 though the supply line 358, the wellhead 350, and into the casing string 320. A volume of spacer fluid 344 or other type of completion fluid can be pumped after the cementing wiper plug 336 to displace the cementing wiper plug 336 down the casing string 320. The cementing wiper plug 336 can push the cement slurry 334 out the float shoe 326 (or other suitable primary cementing equipment), and into the annular space 342 between the casing string 320 and the wellbore 312. In some embodiments, various downhole equipment can be included in the pumping procedure, for example, a plurality of centralizers 340 can be coupled to the casing string 320 to maintain the annular gap within the annular space 342 between the casing string 320 and the wellbore 312. In other embodiments, however, the casing string 320 may be omitted from all or a portion of the wellbore 312 and the principles of the present disclosure can equally apply to an “open-hole” environment. In still other embodiments, however, the primary cementing equipment, e.g., float shoe 326, at the bottom end 330 of the casing string 320 can be drilled out and a liner can be added to extend the length of the wellbore 312.

The service personnel may discover that one or more initial conditions used in the design of the slurry composition 122 have changed. The slurry design 140, pump schedule, and pump unit can be transported out to a remote wellsite. The pump unit, e.g., pump unit 352, can be fluidically coupled to the wellbore, e.g., wellbore 312. The service personnel and/or one or more sensors on the pump unit 352 can determine a change from the slurry composition 122 determined by the model 116 in FIG. 1A. For example, the service personnel and/or pump unit 352 can determine that the local water quality is different, e.g., increase in mineral content, from the local water inputted from the materials inventory 112. In another example, the service personnel can observe a fluid loss event within the wellbore 312 that requires placement of a fluid loss control treatment. This additional fluid loss control treatment may not have been included within the materials inventory 112.

In some embodiments, the service personnel can execute the method 100 from FIG. 1A on the unit controller 360 of the pump unit 352. The method 100 can execute on the unit controller 360 with the current or local material inventory 112 and the set of design parameters 114. The changes to the initial conditions, e.g., the water quality or fluid loss material, can be included in the local material inventory 112 and the updated set of design parameters 114. The model 116 can execute on the unit controller 360. The unit controller 360 can be communicatively coupled to the geographical database 118 via any combination of wired and wireless service, e.g., mobile communication network. The model 116 can step to block 120 to determine a design slurry by comparing the local material inventory 112 and the updated set of design parameters 114 to the datasets within the geographic database 118. The validation 132 of the method 100 can be performed at the remote wellsite or at the service center within laboratory conditions. The test results from the validation 132 can be stored within the geographic database 118. An error value can be generated at step 134 and inputted into the geographic database 118 and/or the model 116. A design of the slurry composition 122 and validated with validation 132 can be outputted as a slurry design 140. The final slurry design 140 can comprise the slurry composition 122 and, in some embodiments, a pump schedule.

In some embodiments, the service personnel can execute the method 100 from FIG. 1A on a user equipment (UE), e.g., a computer system, a laptop computer, a tablet computer, a hand held computer, or similar UE. The service personnel can manually input the final slurry design 140 into the unit controller 360. In some embodiments, the UE can be communicatively connected to the unit controller 360 via wired or wireless means to transfer or transmit the final slurry design 140 to the unit controller 360.

In some embodiments, the service personnel can execute the method 100 from FIG. 1A on a remote computer system communicatively connected via mobile wireless service to the unit controller 360 or a UE. The remote computer system can be a computer system, a cloud computing platform, a virtual computer within a mobile communication system, or any suitable remote computer system.

The computer system at the wellsite may be a computer system suitable for communication and control of the pumping equipment, e.g., a unit controller 360. In FIG. 1A, the method 100 can be performed on a computer system with the model 116 executing on the same computer system, a networked computer system, or combinations thereof. The pumping operation described in FIG. 3 can be directed by a unit controller 360 that establishes control over the pumping operations. A model 116 can be executing on the same unit controller 360, a networked computer system, a remote computer system, or combinations thereof. In some embodiments, the unit controller 360 of FIG. 3 may be an exemplary computer system 400 described in FIG. 4. Turning now to FIG. 4, a computer system 400 suitable for implementing one or more embodiments of the unit controller, for example, unit controller 360, including without limitation any aspect of the computing system associated with the pumping operation of FIG. 3. The computer system 400 may be suitable for implementing one or more embodiments of the storage computer, for example, storage computer 118 of FIG. 1. The computer system 400 may be suitable for implementing one or more embodiments of a remote computer system, for example, a cloud computing system, a virtual network function (VNF) on a network slice of a cloud computing platform, and a plurality of user devices. The computer system 400 includes one or more processors 402 (which may be referred to as a central processor unit or CPU) that is in communication with memory 404, secondary storage 406, input output devices 408, and network devices 410. The computer system 400 may continuously monitor the state of the input devices and change the state of the output devices based on a plurality of programmed instructions. The programming instructions may comprise one or more applications retrieved from memory 404 for executing by the processor 402 in non-transitory memory within memory 404. The input output devices may comprise a Human Machine Interface with a display screen and the ability to receive conventional inputs from the service personnel such as push button, touch screen, keyboard, mouse, or any other such device or element that a service personnel may utilize to input a command to the computer system 400. The secondary storage 406 may comprise a solid state memory, a hard drive, or any other type of memory suitable for data storage. The secondary storage 406 may comprise removable memory storage devices such as solid state memory or removable memory media such as magnetic media and optical media, i.e., CD disks. The computer system 800 can communicate with various networks with the network devices 410 comprising wired networks, e.g., Ethernet or fiber optic communication, and short range wireless networks such as Wi-Fi (i.e., IEEE 802.11), Bluetooth, or other low power wireless signals such as ZigBee, Z-Wave, 6LoWPan, Thread, and WiFi-ah. The computer system 400 may include a long range radio transceiver 412 for communicating with mobile network providers.

In some embodiments, the computer system 400 may comprise a DAQ card 414 for communication with one or more sensors. The DAQ card 414 may be a standalone system with a microprocessor, memory, and one or more applications executing in memory. The DAQ card 414, as illustrated, may be a card or a device within the computer system 400. In some embodiments, the DAQ card 414 may be combined with the input output device 408. The DAQ card 414 may receive one or more analog inputs 416, one or more frequency inputs 418, and one or more Modbus inputs 420. For example, the analog input 416 may include a volume sensor, e.g., a tank level sensor. For example, the frequency input 418 may include a flow meter, i.e., a fluid system flowrate sensor. For example, the Modbus input 420 may include a pressure transducer. The DAQ card 414 may convert the signals received via the analog input 416, the frequency input 818, and the Modbus input 420 into the corresponding sensor data. For example, the DAQ card 414 may convert a frequency input 418 from the flowrate sensor into flow rate data measured in gallons per minute (GPM).

The systems and methods disclosed herein may be advantageously employed in the context of wellbore servicing operations, particularly, in relation to the design of a slurry composition 122 for a cement operation as disclosed herein.

In some embodiments, a method 100 and/or a monitoring process executing on a unit controller 360 of a pump unit 352 can receive a periodic dataset indicative of a pumping operation. The method 100 and/or the monitoring process can determine a change in the materials inventory 112 and/or the wellbore environment within the set of design parameters 114 by comparing the periodic datasets to materials inventory 112 and design parameters 114. The method 100 and/or monitoring process can identify the change in the materials inventory 112 and/or wellbore environment and a response to the identified change. The method 100 and/or monitoring process can utilize the model 116 to modify and/or determine the final slurry design 140, the pump schedule, or combinations thereof in response to identifying the change. The model 116 can execute on the unit controller, on a computer system local to the remote wellsite, or on a remote computer system.

### ADDITIONAL DISCLOSURE

The following are non-limiting, specific embodiments in accordance with the present disclosure:

A first embodiment, which is method of preparing and pumping a cement slurry, comprising retrieving, by a model executing on a computer system, a material inventory and a set of design parameters for the cement slurry; determining, by the model, a design slurry composition based on at least one of the set of design parameters; determining, by the model using a machine learning process, a predicted thickening time by comparing the design slurry composition, the material inventory, and the set of design parameters to a plurality of datasets for previous cement jobs performed within a defined geographic region and stored within a geographic database; generating a final slurry design in response to a set of validation results of a slurry test sample being within a threshold range of a target value; preparing the cement slurry according to the final slurry design; and pumping a cement job with the prepared cement slurry.

A second embodiment, which is the method of the first embodiment, wherein the set of design parameters comprise a thickening time requirement, a fluid loss control requirement, a rheology requirement, a stability requirement, a compressive strength requirement, a density requirement, or combinations thereof.

A third embodiment, which is the method of the first or second embodiment, wherein the material inventory comprises geographical cement, a volume of local water, one or more supplementary cementitious material (SCM), density additives, one or more chemical additives, or combinations thereof.

A fourth embodiment, which is the method of any of the first through the third embodiments, wherein the geographical cement is a cementitious material that is sourced, mined, blended, manufactured, or combinations thereof specific to a geographic area; and wherein the source of local water is specific to the geographic area.

A fifth embodiment, which is the method of any of the first through the fourth embodiments, wherein the one of more SCM is selected from a group consisting of fly ash, ground blast furnace slag, silica fume, calcium carbonate, natural pozzolans, and combinations thereof; wherein the density additives is selected from a group consisting of weighting agents, lightweight additives, mechanical property enhancing additives, and combinations thereof; and wherein the one or more chemical additives is selected from a group consisting of accelerators, retarders, fluid loss control additives, strength modifiers, weighting agents, lost circulation control additives, rheological modifiers, polymeric agents, and combinations thereof.

A sixth embodiment, which is the method of any of the first through the fifth embodiments, further comprising comparing the predicted thickening time to the validation test results; and returning to the determining a design slurry composition step in response to the comparison being below a threshold value.

A seventh embodiment, which is the method of any of the first through the sixth embodiments, wherein generating a test sample of the design slurry composition in response to the predicted thickening time or strength being greater than the threshold value.

An eighth embodiment, which is the method of any of the first through the seventh embodiments, further comprising training the model by inputting a set of validation results into the geographic database in response to completing a validation test of the test sample.

A ninth embodiment, which is the method of any of the first through the eighth embodiments, wherein the slurry design comprises the slurry composition and a pump schedule.

A tenth embodiment, which is the method of any of the first through the ninth embodiments, further comprising transporting a slurry design and a pump unit to a remote wellsite; fluidically coupling a pump unit to a wellbore; beginning a pumping operation by a unit controller on the pump unit; retrieving, by the unit controller, one or more datasets of periodic pumping data indicative of the pumping operation; and mixing a slurry design, by the pump unit, per the pump schedule.

An eleventh embodiment, which is a method of placing a cement slurry within a wellbore penetrating a formation, comprising comparing, by a unit controller on a pumping unit, a slurry design, a material inventory including a geographical cement, and a set of job parameters to a current water supply and a current wellbore environment; retrieving, by a model executing on the unit controller, an updated material inventory and a set of updated design parameter; determining, by the model, a revision two slurry composition based on at least one of the set of updated design parameters; determining, by the model using a machine learning process, a predicted thickening time by comparing the revision two slurry composition, the updated material inventory, and the set of updated design parameters to a plurality of datasets within a geographic database; generating a slurry design in response to a set of validation results of a test sample exceeding a threshold value; and pumping a cement job with the revision two slurry composition.

A twelfth embodiment, which is the method of the eleventh embodiment, wherein the unit controller is communicatively connected to the geographic database, and wherein the geographical database comprise datasets of validation tests of slurry designs comprising a geographical cement.

A thirteenth embodiment, which is the method of any of the eleventh and the twelfth embodiments, wherein the updated material inventory comprises the current water supply; and wherein the set of updated design parameters comprise the current wellbore environment.

A fourteenth embodiment, which is the method of any of the eleventh through the thirteenth embodiments, further comprising alerting, by the unit controller, of a comparison value exceeding a threshold value.

A fifteenth embodiment, which is the method of any of the eleventh through the fourteenth embodiments, wherein the geographical cement is a cementitious material that is sourced, mined, blended, manufactured, or combinations thereof from a specific geographic area.

A sixteenth embodiment, which is a cementing system at a remote wellsite, comprising a pump unit fluidically connected to a wellbore; a controller comprising a processor and a non-transitory memory, configured to: retrieve, by a model executing on the controller, a material inventory and a set of design parameters, and wherein the material inventory comprises a geographical cement and a volume of local water; determine, by the model, a design slurry composition based on at least one of the set of design parameters; determine, by the model using a machine learning process, a predicted thickening time by comparing the design slurry composition, the material inventory, and the set of design parameters to a plurality of datasets within a geographic database; generate a slurry design in response to a set of validation results of a test sample exceeding a threshold value; and control a pumping operation for a placement of the slurry design per a pump schedule.

A seventeenth embodiment, which is the system of the sixteenth embodiment, wherein the test sample is generated from the design slurry composition.

An eighteenth embodiment, which is the system of the sixteenth embodiment, wherein the set of validation results are generated at the remote wellsite or in a laboratory environment remote from the remote wellsite.

A nineteenth embodiment, which is the system of the sixteenth embodiment, wherein the controller is communicatively connected to the geographic database by wireless communication, wired communication, or combinations thereof.

A twentieth embodiment, which is the system of any of the sixteenth through the nineteenth embodiments, further comprising train the model by inputting the set of validation results of the test sample into the geographic database.

While embodiments have been shown and described, modifications thereof can be made by one skilled in the art without departing from the spirit and teachings of this disclosure. The embodiments described herein are exemplary only, and are not intended to be limiting. Many variations and modifications of the embodiments disclosed herein are possible and are within the scope of this disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rl, and an upper limit, Ru, is disclosed, any number falling within the range is specifically disclosed. In particular, the following numbers within the range are specifically disclosed: R=Rl+k*(Ru−Rl), wherein k is a variable ranging from 1 percent to 100 percent with a 1 percent increment, i.e., k is 1 percent, 2 percent, 3 percent, 4 percent, 5 percent, . . . 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim is intended to mean that the subject element is required, or alternatively, is not required. Both alternatives are intended to be within the scope of the claim. Use of broader terms such as comprises, includes, having, etc. should be understood to provide support for narrower terms such as consisting of, consisting essentially of, comprised substantially of, etc.

Accordingly, the scope of protection is not limited by the description set out above but is only limited by the claims which follow, that scope including all equivalents of the subject matter of the claims. Each and every claim is incorporated into the specification as an embodiment of the present disclosure. Thus, the claims are a further description and are an addition to the embodiments of the present disclosure. The discussion of a reference herein is not an admission that it is prior art, especially any reference that may have a publication date after the priority date of this application. The disclosures of all patents, patent applications, and publications cited herein are hereby incorporated by reference, to the extent that they provide exemplary, procedural, or other details supplementary to those set forth herein.

What is claimed is:

1. A cementing system for use at a remote wellsite, comprising:
a pump unit fluidically connected to a wellbore;
a controller of the pump unit comprising a processor and a non-transitory memory, configured to:
retrieve, by a model executing on the controller, a material inventory and a set of design parameters, and wherein the material inventory comprises a geographical cement and a source of local water;
determine, by the model, a design slurry composition based on at least one of the set of design parameters;
determine, by the model using a machine learning process, a predicted thickening time by comparing the design slurry composition, the material inventory, and the set of design parameters to a plurality of datasets within a geographic database;
generate a final slurry design in response to a set of validation results of a test sample exceeding a threshold value; and
control a pumping operation for a placement of the cement slurry per a pump schedule.

2. The system of claim 1, wherein:
the test sample is generated from the design slurry composition.

3. The system of claim 1, wherein the set of validation results are generated at the remote wellsite or in a laboratory environment remote from the remote wellsite.

4. The system of claim 1, wherein the controller is communicatively connected to the geographic database by wireless communication, wired communication, or combinations thereof.

5. The system of claim 1, further comprising:
train the model by inputting the set of validation results of the test sample into the geographic database.

6. A method of placing a cement slurry within a wellbore penetrating a formation, comprising:
comparing, by a unit controller on a pumping unit, a slurry design, a material inventory including a geographical cement, and a set of job parameters to a current water supply and a current wellbore environment;
retrieving, by a model executing on the unit controller, an updated material inventory and a set of updated design parameters;
determining, by the model, a revision two slurry composition based on at least one of the set of updated design parameters;
determining, by the model using a machine learning process, a predicted thickening time by comparing the revision two slurry composition, the updated material inventory, and the set of updated design parameters to a plurality of datasets within a geographic database;
generating a revision two slurry design in response to a set of validation results of a test sample exceeding a threshold value; and
pumping a cement job with the cement slurry comprising the revision two slurry design.

7. The method of claim 6, wherein:
the unit controller is communicatively connected to the geographic database, and wherein the geographical database comprise datasets of validation tests of corresponding slurry designs comprising a geographical cement.

8. The method of claim 6, wherein:
the updated material inventory comprises the current water supply; and
wherein the set of updated design parameters comprise the current wellbore environment.

9. The method of claim 6, further comprising:
alerting, by the unit controller, of a comparison value exceeding a threshold value.

10. The method of claim 6, wherein:
the geographical cement is a cementitious material that is sourced, mined, blended, manufactured, or combinations thereof from a specific geographic area.

11. A method of preparing and pumping a cement slurry, comprising:
retrieving, by a model executing on a computer system, a material inventory and a set of design parameters for the cement slurry;
determining, by the model, a design slurry composition based on at least one of the set of design parameters;
determining, by the model using a machine learning process, a predicted thickening time by comparing the design slurry composition, the material inventory, and the set of design parameters to a plurality of datasets for previous cement jobs performed within a defined geographic region and stored within a geographic database;
generating a final slurry design in response to a set of validation results of a slurry test sample being within a threshold range of a target value;
preparing the cement slurry according to the final slurry design; and
pumping a cement job with the prepared cement slurry.

12. The method of claim 11, wherein:
the set of design parameters comprise a thickening time requirement, a fluid loss control requirement, a rheology requirement, a stability requirement, a compressive strength requirement, a density requirement, or combinations thereof.

13. The method of claim 11, wherein:
the material inventory comprises geographical cement, local water, one or more supplementary cementitious material (SCM), density additives, one or more chemical additives, or combinations thereof.

14. The method of claim 13, wherein:
the geographical cement is a cementitious material that is sourced, mined, blended, manufactured, or combinations thereof specific to a geographic area; and
wherein the source of local water is specific to the geographic area.

15. The method of claim 13, wherein
the one of more SCM is selected from a group consisting of fly ash, ground blast furnace slag, silica fume, calcium carbonate, natural pozzolans, and combinations thereof;
wherein the density additives is selected from a group consisting of weighting agents, lightweight additives, mechanical property enhancing additives, and combinations thereof, and
wherein the one or more chemical additives is selected from a group consisting of accelerators, retarders, fluid loss control additives, strength modifiers, weighting agents, lost circulation control additives, rheological modifiers, polymeric agents, and combinations thereof.

16. The method of claim 11, further comprising:
comparing the predicted thickening time to the validation test results; and
returning to the determining a design slurry composition step in response to the comparison being below a threshold value.

17. The method of claim 11, further comprising:
generating a test sample of the design slurry composition in response to the predicted thickening time or strength being within the threshold range of the target value.

18. The method of claim 11, further comprising:
updating the model by inputting a set of validation results into the geographic database in response to completing a validation test of the test sample.

19. The method of claim 11, wherein the slurry design comprises the design slurry composition and a pump schedule.

20. The method of claim 11, further comprising:
transporting a slurry design and a pump unit to a remote wellsite;
fluidically coupling a pump unit to a wellbore;
beginning a pumping operation by a unit controller on the pump unit;
retrieving, by the unit controller, one or more datasets of periodic pumping data indicative of the pumping operation; and
mixing a slurry design, by the pump unit, per a pump schedule.
